(19) United States
(12) Patent Application Publication
(10) Pub. No.: US 2005/0252448 A1
(43) Pub. Date: Nov. 17, 2005

(54) APPARATUS AND METHOD FOR PREVENTING RESIDUAL GASES FROM POLLUTING WAFER

(76) Inventors: Cheng-Hsien Tai, Hsinchu City (TW); Kuo-Hwa Huang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,948

(22) Filed: Dec. 7, 2004

(30) Foreign Application Priority Data
May 13, 2004 (TW) 93113403

(51) Int. Cl. C23C 16/00

(52) U.S. Cl. 118/715; 427/248.1

(57) ABSTRACT

An apparatus for preventing a residual gas from polluting a wafer is provided. The apparatus mainly includes a chemical vapor deposition (CVD) station, a delivery pipeline, a purge pipeline and a check valve. The delivery pipeline is connected to the CVD station and the purge pipeline is connected to the delivery pipeline. By disposing the check valve on the purge pipeline, any residual gases inside the purge pipeline is prevented from flowing back into the delivery pipeline and polluting the wafer.

### CROSS-REFERENCE TO RELATED APPLICATION

This application claims the priority benefit of Taiwan application serial no. 93113403, filed May 13, 2004.

### BACKGROUND OF THE INVENTION

1. Field of the Invention

The present invention relates to a semiconductor apparatus and a processing method. More particularly, the present invention relates to an apparatus and method for preventing a residual gas from polluting a wafer.

2. Description of Related Art

Chemical vapor deposition (CVD) is a thin film deposition technique for depositing material over the surface of a wafer. The process involves reacting chemical substances (typically, gaseous reactants) together inside a reaction chamber so that a solid layer is slowly grown over the wafer. The applications of CVD are extensive. In fact, most of the thin films required by a semiconductor device, whether they are conductors, semiconductors or dielectric materials, are prepared through a chemical vapor deposition process. Furthermore, because the films are formed by a chemical reaction between gaseous reactants in chemical vapor deposition process, the crystallinity and stoichiometry of the deposited material is much better than one formed by the traditional sputtering method. Hence, in the fabrication of advance semiconductor devices, CVD has become the principal method for forming thin films.

To deposit a thin film over a wafer in a CVD process, the wafer is placed inside a CVD station. Through a delivery pipeline, gaseous reactants are transported into the reaction chamber of the CVD station. Thereafter, the gaseous reactants react inside the reaction chamber to form solid product and then the solid product is deposited on the surface of the wafer. For example, in a high-density plasma (HDP) chemical vapor deposition (CVD) process, silane (SiH₄) and oxygen (O₂) are used as the gaseous reactants to form a silicon oxide thin film. Hence, silane and oxygen are delivered into the CVD station through a delivery pipeline so that they can react together to produce a layer of silicon oxide (SiO₂) on the surface of a wafer. However, the delivery pipeline can easily hide some residual gaseous reactants. After a definite period, these residual gaseous reactants may react to form fine particles. Therefore, when the CVD apparatus is re-started after remaining in a standby (or off) mode for some time, the residual reactants and the particles may enter the CVD reaction chamber and some may stick to the surface of the wafer as pollutants.

FIG. 1 is a top view of a polluted wafer. As shown in FIG. 1, jet type particles are deposited on the surface of a wafer 10 as soon as a CVD station in a standby (or off) state is restarted when the delivery pipeline hides some residual gaseous reactants and micro-particles. The jet type particles may so adversely affect the quality and yield of the product that the wafer may have to be scrapped. Even if the delivery pipeline is purged before initiating a CVD operation, it is still difficult to prevent the micro-particles from polluting the wafer. In other words, a way is needed to prevent any residual gases inside the delivery pipeline from flowing back into the CVD reaction chamber causing a wafer pollution problem.

### SUMMARY OF THE INVENTION

Accordingly, the present invention is directed to an apparatus and method thereof for preventing any residual gases inside a delivery pipeline from back flowing and polluting a wafer during a chemical vapor deposition process.

According to an embodiment of the present invention, the apparatus mainly includes a chemical vapor deposition chamber, a gas storage tank, a delivery pipeline, a purge pipeline, a diversion valve and a check valve. The chemical vapor deposition chamber has a receptacle for placing a wafer. The gas storage tank stores and supplies at least a gaseous reactant. The delivery pipeline connects the gas storage tank and the chemical vapor deposition chamber together. One end of the purge pipeline is connected to the delivery pipeline. The diversion valve is disposed at the junction between the delivery pipeline and the purge pipeline. The check valve is disposed in the purge pipeline to prevent the back flow of residual gases back into the delivery pipeline and pollute the wafer.

The present invention also provides a method for preventing a residual gas from polluting a wafer. The method is applied in an apparatus capable of preventing a residual gas from polluting a wafer. The apparatus includes at least a chemical vapor deposition chamber, a delivery pipeline and a purge pipeline such that the delivery pipeline and the chemical vapor deposition chamber are connected, and the purge pipeline and the delivery pipeline are connected. First, a purging process is carried out by passing a purging gas into the delivery pipeline and divert the gas flow so that the purging gas exhausts through the purge pipeline to remove any residual gases from the delivery pipeline. Thereafter, a check valve disposed in the purge pipeline prevents any residual gases from back flowing into the delivery pipeline.

In one embodiment of the present invention, the aforementioned apparatus for preventing a residual gas from polluting a wafer further includes a mass flow controller disposed along the delivery pipeline. The mass flow controller is positioned between the gas storage tank and the diversion valve for controlling the gas flow rate.

In one embodiment of the present invention, the aforementioned apparatus for preventing a residual gas from polluting a wafer further includes a first shutoff valve disposed along the delivery pipeline. The first shutoff valve is positioned between the diversion valve and the chemical vapor deposition chamber for controlling the flow of gas into the chemical vapor deposition chamber.

In one embodiment of the present invention, the aforementioned apparatus for preventing a residual gas from polluting a wafer further includes gas withdrawal device attached to another end of the purge pipeline. In addition, a gas exhaust pipeline is installed between the chemical vapor deposition chamber and the gas withdrawal device so that exhaust gases within the chemical vapor deposition chamber can be removed using the gas withdrawal device. Furthermore, a second shutoff valve can be disposed on the gas exhaust pipeline for controlling the flow of gases.

In one embodiment of the present invention, the gas storage tank supplies at least an inert gas for purging the delivery pipeline or carrying gaseous reactants.

With the addition of a check valve in the purge pipeline, the residual gases inside the delivery pipeline carried away by inert gas flowing from the purge pipeline in a delivery pipeline purging process is prevented from back flowing into the delivery pipeline again. Therefore, pollution of wafer by the residual gases inside the delivery pipeline is effectively reduced during a chemical vapor deposition.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a polluted wafer.

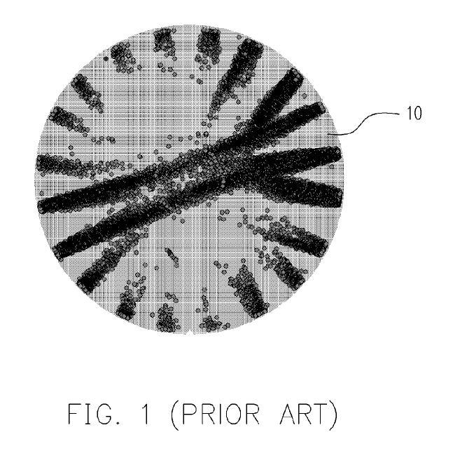

FIG. 2 is a schematic diagram showing an apparatus for preventing a residual gas from polluting a wafer according to one embodiment of the present invention.

FIG. 3 is a top view of a wafer processed by an apparatus designed to preventing a residual gas from polluting a wafer according to one embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

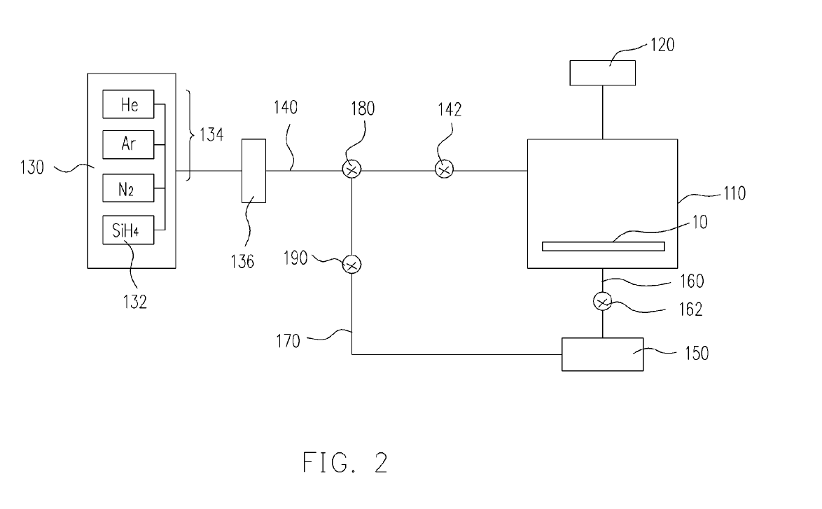

FIG. 2 is a schematic diagram showing an apparatus for preventing residual gases from polluting a wafer according to one embodiment of the present invention. The apparatus shown in FIG. 2 mainly includes a chemical vapor deposition chamber 110, an oxygen supply device 120, a gas storage tank 130, a delivery pipeline 140, a gas withdrawal device 150, an exhaust pipeline 160, a purge pipeline 170, a diversion valve 180 and a check valve 190. The chemical vapor deposition chamber 110 is, for example, an atmospheric pressure chemical vapor deposition chamber, a low-pressure chemical vapor deposition chamber, a plasma-enhanced chemical vapor deposition chamber or a high-density plasma chemical vapor deposition chamber.

The chemical vapor deposition chamber 110 has a reaction chamber for housing at least a wafer 10. The oxygen supply device 120 is connected to the reaction chamber of the chemical vapor deposition chamber 110 for providing oxygen. The oxygen is used for sustaining a burning reaction to keep the chemical vapor deposition chamber 110 maintained at a high temperature and reacting with other gaseous reactants subsequently supplied into the chamber to form solid state products. Clearly, the oxygen supply device 120 need not be the only way to supply the oxygen necessary for the reaction inside the reaction chamber 110. In fact, the oxygen may be stored inside the gas storage tank 130 and fed to the reaction chamber 110 through another delivery pipeline.

The gas storage tank 130 is a storage unit for providing gaseous reactants 132 (for example, silane SiH₄) and inert gas 134 (for example, nitrogen N₂, argon Ar or helium He). The inert gas 134 (illustrated using nitrogen N₂ in the present embodiment) serves as a gas for purging the pipeline and a gaseous carrier (illustrated using argon Ar and helium He in the present embodiment).

The delivery pipeline 140 connects the gas storage tank 130 and the chemical vapor deposition chamber 110 together. Through the delivery pipeline 140, gaseous reactants 132 and inert gases 134 are delivered to the chemical vapor deposition chamber 110.

The exhaust pipeline 160 connects the gas withdrawal device 150 to the chemical vapor deposition chamber 110. Through the gas withdrawal device 150 and the exhaust pipeline 160, exhaust gases inside the chemical vapor deposition chamber 110 are removed.

One end of the purge pipeline 170 is connected to the delivery pipeline 140 while another end of the purge pipeline 170 is connected to the gas withdrawal device 150. The diversion valve 180 is disposed at the junction between the delivery pipeline 140 and the purge pipeline 170, and the check valve 190 is disposed on the purge pipeline 170. In addition, a mass flow controller 136 can be disposed on the delivery pipeline 140 and positioned between the gas storage tank 130 and the diversion valve 180 for controlling the gas flow rate. A shutoff valve 142 may be disposed on the delivery pipeline 140 between the diversion valve 180 and the chemical vapor deposition chamber 110 for controlling the flow of gas into the chemical vapor deposition chamber 1110. Furthermore, another shutoff valve 162 may be disposed on the exhaust pipeline 160 between the chemical vapor deposition chamber 110 and the gas withdrawal device 150 for controlling the flow of exhaust gas from the chemical vapor deposition chamber 110.

With an additional check valve 190 disposed on the purge pipeline 170, any residual gases inside the delivery pipeline 140 exhausted through the purge pipeline 170 is prevented from flowing back into the delivery pipeline 140 to pollute the wafer during a chemical vapor deposition.

The present invention also provides a method of preventing residual gases from polluting a wafer. The method uses the aforementioned apparatus. First, a purging operation is carried out by passing a purging gas (such as nitrogen) into the delivery pipeline 140 and changing the direction of flow so that the purging gas exhausts from the purge pipeline 170 and removes any residual gases (such as silane) inside the delivery pipeline 140. The check valve 190 disposed on the purge pipeline 170 serves to prevent the back flow of any residual gas into the delivery pipeline 140 and pollute the wafer inside the chemical vapor deposition chamber 110.

Before performing a chemical vapor deposition process to form a layer over the wafer, a pre-heating process is carried out by passing oxygen from the oxygen supply device 120 into the chemical vapor deposition chamber 110 so that a burning reaction is sustained to heat up the reaction chamber. Thereafter, the delivery pipeline 140 is purged by passing an inert gas 134 (for example, nitrogen N₂ in the present embodiment) into the delivery pipeline 140. The diversion valve 180 is used to change the direction of gas flow so that the inert gas 134 carries the residual gases 132 (for example, silane SiH₄ in the present embodiment) inside the delivery pipeline 140 away through the purge pipeline 170.

In the method of the present invention, a check valve 190 is disposed in the purge pipeline 170 so that any residual gases inside the delivery pipeline 140 is prevented from flowing back into the delivery pipeline 140. Thus, when the chemical vapor deposition chamber 110 is re-started from an idle state, the delivery pipeline 140 is free from any residual gases and pollution of wafer by the residual gases inside the delivery pipeline is effectively reduced. Obviously, the purging gas for removing residual gases from the delivery pipeline 140 is not limited to inert gas. The purging process can be carried out using gaseous reactants.

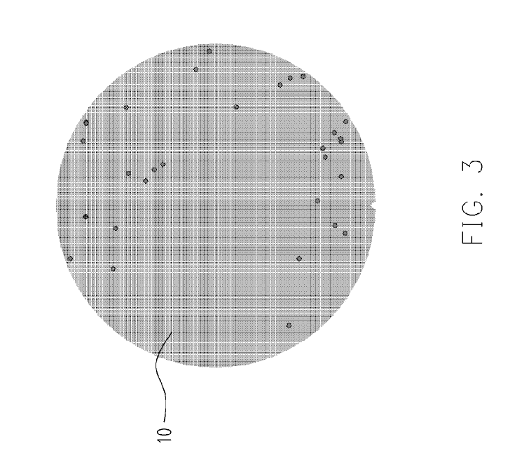

FIG. 3 is a top view of a wafer processed by an apparatus designed to preventing residual gases from polluting a wafer according to one embodiment of the present invention. The check valve on the purge pipeline prevents any purged residual gases from flowing back into the delivery pipeline. Therefore, the wafer 10 is pollutant-free because any polluting gases have been purged from the delivery pipeline prior to re-starting the chemical vapor deposition chamber.

In summary, the residual gases inside the delivery pipeline carried away by gas flowing from the purge pipeline in a delivery pipeline purging process is prevented from back flowing into the delivery pipeline by a check valve on the purge pipeline. Therefore, the residual gases inside the delivery pipeline are prevented from polluting any wafer during a chemical vapor deposition.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An apparatus for preventing residual gases from polluting a wafer, comprising:
a chemical vapor deposition chamber, for housing at least a wafer;
a gas storage tank, for providing at least a gaseous reactant;
a delivery pipeline, disposed between the gas storage tank and the chemical vapor deposition chamber;
a purge pipeline, having one end connected to the delivery pipeline;
a diversion valve, disposed at the junction between the delivery pipeline and the purge pipeline; and
a check valve, disposed on the purge pipeline for preventing any residual gases from back flowing into the delivery pipeline.

2. The apparatus of claim 1, wherein the apparatus further comprises a mass flow controller disposed on the delivery pipeline and positioned between the gas storage tank and the diversion valve.

3. The apparatus of claim 1, wherein the apparatus further comprises a first shutoff valve disposed on the delivery pipeline and positioned between the diversion valve and the chemical vapor deposition chamber.

4. The apparatus of claim 1, wherein the apparatus further comprises a gas withdrawal device connected to another end of the purge pipeline.

5. The apparatus of claim 4, wherein the apparatus further comprises an exhaust pipeline for connecting the chemical vapor deposition chamber and the gas withdrawal device.

6. The apparatus of claim 5, wherein the apparatus further comprises a second shutoff valve disposed on the exhaust pipeline.

7. The apparatus of claim 1, wherein the gas storage tank supplies at least an inert gas.

8. A method of preventing residual gases from polluting a wafer with an apparatus having at least a chemical vapor deposition chamber, a delivery pipeline connected to the chemical vapor deposition chamber and a purge pipeline connected to the delivery pipeline, comprising the steps of:
performing a purging process by providing a purging gas into the delivery pipeline and changing a flow direction of the purging gas so that the purging gas removes the residual gases inside the delivery pipeline via the purge pipeline; and
utilizing a check valve disposed on the purge pipeline to prevent the residual gases from flowing back into the delivery pipeline.

9. The method of claim 8, wherein the purging gas comprises nitrogen.

10. The method of claim 8, wherein one of the residual gases comprises silane.
